(19) United States
(12) Patent Application Publication
(10) Pub. No.: US 2015/0149104 A1
(43) Pub. Date: May 28, 2015

(54) Motion Tracking Solutions Using a Self Correcting Three Sensor Architecture

(71) Applicants: John Baker, Hayward, CA (US); Remigio Perales, Oberlin, OH (US)

(72) Inventors: John Baker, Hayward, CA (US); Remigio Perales, Oberlin, OH (US)

(21) Appl. No.: 14/550,894

(22) Filed: Nov. 21, 2014

Related U.S. Application Data
(60) Provisional application No. 61/907,393, filed on Nov. 22, 2013.

(51) Int. Cl. G01P 21/00; G01R 33/00

(52) U.S. Cl. CPC G01P 21/00; G01R 33/0035
USPC 702/87; 702/104

(57) ABSTRACT

A system of sensors including 1) an accelerometer, 2) a magnetometer, and 3) a gyroscope, combined with a zero crossing error correction algorithm, as well as a method of using those sensors with the zero crossing error correction algorithm, for orientation motion tracking applications, including sports and athletics training, animation for motion picture and computer gaming industry, 3D joysticks, and peripherals for computer gaming industry, as well as medical and health diagnosis and monitoring systems.

### CROSS REFERENCE TO RELATED APPLICATION

This application claims the benefits of U.S. Provisional Application No. 61/907,393, entitled “Motion Tracking Alternatives Using a Self Correcting MEMS based Three Sensor Architecture,” and filed on Nov. 22, 2013, the entire disclosure of which is incorporated by reference as part of the specification of this application.

### BACKGROUND

Motion tracking is concerned with measuring the position of an object as a function of time. In this context there are two types of motion tracking that are of interest. One is tracking the absolute position of an object without regard to its orientation in space. This can be thought of as tracking an object's center of mass. The second concept is tracking an object's orientation in space which requires accurately tracking rotations. This patent is primarily concerned with the latter.

Orientational motion tracking can be accomplished using one or more sensors (usually an accelerometer, magnetometer or gyroscope) and an algorithm which is applied to the sensor outputs to determine sensor orientation.

The concept of using all or a subset of an accelerometer, gyroscope and magnetometer in combination to perform motion tracking has been proposed previously in numerous works. However, the prior art in this area either is limited in applicability or involves complicated error correction schemes.

The simplest of the limited application systems include accelerometer-only systems and magnetometer-only systems. In the accelerometer-only systems, one or more accelerometers are used to determine the orientation of an object about the Earth's gravitational field. In the magnetometer-only systems, one or more magnetometers is used to determine the orientation of an object about the Earth's magnetic field. Each of these systems suffers from the fact that they only determine orientation about a single axis (i.e. either the axis defined by the direction of Earth's gravitational field or an axis defined by the Earth's magnetic field.

Motion tracking systems also exist that use only gyroscopes, which measure rotational velocities, and those that use only accelerometers, which measure rotational accelerations. Strictly speaking, a single accelerometer measures linear acceleration, not rotations; but, if paired geometrically, a set of accelerometers can give angular acceleration. All the dynamical quantities involved in biomechanical motion can be derived from these single sensor systems, as explained below. However, all real gyroscopes and accelerometers suffer from DC drift which cause errors in the calculated orientation that increase unbounded with time.

Slightly more complicated architectures in the “limited application” category use a combination of 3D gyroscope and 3D magnetometer to determine full 3D orientation in space without unbounded sensor drift induced errors. However, these systems are also of limited application since the accelerometer data can only be used to determine orientation in the absence of external accelerations. Therefore these systems are only of use in systems that are not undergoing any large accelerations.

Systems exist that use a 3D accelerometer, a 3D magnetometer and a 3D gyroscope, and combine all three sensors to determine orientation in both the static or low acceleration state, as well as determining orientation when an object is accelerating. In this approach, the output of the 3D gyroscope is mathematically integrated in time to obtain the three orientation angles. However as stated above, all real gyroscopes suffer from DC drift which makes the orientation angles inaccurate for long timespans.

For example, published patent application US 2007/0032748 A1 of McNeill (abandoned) uses a correction algorithm in which the acceleration and magnetometer data are used at each and every time step to correct for the gyroscope data. This procedure is computationally expensive since it requires multiple integrations and the calculation of an orientation matrix at each time step. This procedure is also data intensive since it requires data from all three sensor types at each time step to perform the orientation calculations. Finally, this procedure is likely to be imprecise for applications in which large accelerations are present (e.g. motion tracking in sports applications). This is due to the fact that any orientation data obtained from the accelerometers is only completely accurate when the system is not accelerating. At these points the orientation relative to earth's gravity can be unambiguously determined. When the system is undergoing large accelerations, however, the accelerometers become inaccurate at determining orientation. Since the prior art uses the acceleration at every time step, it is expected to lose accuracy in applications where large accelerations occur.

The following is an explanation of the methods that the prior art uses to measure orientation data and track orientational motion using one or more of a 3D accelerometer, a 3D magnetometer and a 3D gyroscope. The 3D sensors measure quantities along three local axes. The measured quantities are as follows:

1) Accelerometer—if the sensor is not accelerating, the accelerometer gives the direction of the earth's gravitational field \vec{g}. If the sensor is accelerating at a rate \vec{A}, it gives the vector sum of \vec{g} and \vec{A}.

2) Magnetometer—The magnetometer measures the Earth's geomagnetic field direction \vec{B}.

3) Gyroscope—The gyroscope measures rotational velocity \vec{ω} about the local coordinate axes.

The coordinate system which rotates with three sensors is called the local coordinate system (LCS). The global coordinate system (GCS) is a fixed coordinate system and does not move with the sensors. The two coordinate systems are related by rotations about the x, y, and z axis, termed the roll, pitch and yaw angles. The task in determining the orientation of a segment is to obtain the roll, pitch and yaw angles of the LCS relative to the GCS as shown in FIG. 1.

In the global coordinate system, \vec{g} points in the z direction, while \vec{B} points in the x, z plane. In the rotated LCS system these vectors have components (gₓ, g_{y}, g_{z}) and (Bₓ, B_{y}, B_{z}) respectively. Given these components of \vec{B} and \vec{g} in the local coordinate system, the roll pitch and yaw angles can be calculated exactly from:

$${R}_{X} ( φ ) {R}_{Y} ( θ ) {R}_{Z} ( ψ ) ( \begin{matrix}\vert B \vert cos ( δ ) \\ 0 \\ \vert B \vert sin ( δ )\end{matrix} ) = ( \begin{matrix}{B}_{X} \\ {B}_{Y} \\ {B}_{Z}\end{matrix} ) , and$$

$${R}_{X} ( φ ) {R}_{Y} ( θ ) {R}_{Z} ( ψ ) ( \begin{matrix}0 \\ 0 \\ \vert \vec{g} \vert\end{matrix} ) = ( \begin{matrix}{g}_{X} \\ {g}_{Y} \\ {g}_{Z}\end{matrix} ) .$$

In the above equations, Rₓ, R_{y} and R_{z} are the well known rotation matrices in three dimensional Cartesian space, |g| is the magnitude of the acceleration of gravity, |B| is the Earth's magnetic field value and δ is the inclination angle of the Earth's magnetic field. Each of these quantities is known a priori and may be used to obtain a solution to the equations. However, there are also well known methods to solve these equations in which the values of |\vec{g}|, |\vec{B}| and δ all drop out of the final solution so that their exact values are not needed to obtain the orientation angles.

It should also be noted that if one or more sensors are not aligned, the sensor outputs may first be mathematically rotated before using the above algorithm. For example, FIG. 2 shows a sensor node that is fabricated with a magnetometer that is rotated 90 degrees relative to the accelerometer and gyroscope.

In this case, the magnetometer outputs are first rotated by −π/2 with the rotation matrix R_{z} and this result is then used in the equations to determine the orientation angles. So having the sensor coordinate systems aligned is not critical for the orientation algorithm to work but is the simplest architecture to deal with mathematically.

### Kinematical Equations

Using the above set of equations, the orientation of a single segment can be obtained using the accelerometer and magnetometer. However, since the accelerometers can only measure \vec{g} when there are no accelerations involved, these equations can only be used for very slowly changing motions. To get the dynamical motion the rotational velocities measured using the gyroscopes or the rotational accelerations using the accelerometers must be used.

Since a single accelerometer measures linear acceleration, two accelerometers must be paired as shown in FIG. 3 in order to obtain rotational acceleration.

In the scheme shown in FIG. 3, two accelerometers labeled A1 and A2 are separated by a distance r. Each accelerometer measures linear accelerations (Aₓ, A_{y}, A_{z}) relative to its local coordinate system. The angular acceleration about the z axis (out of the page) is now given by

$${α}_{Z} = \frac{1}{r} ( {A}_{2 x} - {A}_{1 x} ) .$$

There are therefore three kinematical parameters of interest in determining the movements involved in the motion of a single biomechanical segment:

1) The orientation angles about the x, y, and z axes (i.e. roll, pitch and yaw denoted by θₓ, θ_{y}, θ_{z});

2) The rate of change of the orientation angles (denoted by ωₓ, ω_{y}, ω_{z}); and

3) The rate of acceleration of the angular variables (denoted by αₓ, α_{y}, α_{z})

In principle, each of these quantities is related to one another, and knowledge of any one kinematical parameter is sufficient to determine the other two. For example, given measurements of θₓ as a function of time, ωₓ and αₓ can be determined from the following mathematical expressions:

$${ϖ}_{x} = \frac{d {θ}_{x}}{d t} , {α}_{x} = \frac{{d}^{2} {θ}_{x}}{d {t}^{2}}$$

Conversely, given the accelerations αₓ (and assuming zero initial velocity) the positions and velocities can be determined from:

ω̅ₓ=∫αₓdt,θₓ=∫αₓdt)dt

However, while it is mathematically possible to determine the kinematical quantities in this way, in practice significant errors will occur due to three limitations:

1) The finite data rate that can be obtained from low cost sensors.

2) The constant DC offset inherent in all real sensors.

3) The possibility of sensor saturation during rapid motions.

### Finite Data Rate

The deduced error in the gyroscope only and accelerometer only systems can be examined by considering the periodic motion shown in FIG. 4. Here, a runner's arm is swinging from negative 30 degrees to positive 30 degrees periodically. We can simulate this motion as a sine wave and calculate the effects of sampling the actual movements using a 1 kHz data rate for both the accelerometer-only and gyroscope-only setups.

### Error Due to Finite Data Rate

Given a system that measures the motion in FIG. 5 using accelerometers, we can deduce expressions for the yaw angle θ_{z} of the upper arm segment. Assume the segment starts at θ=0 with zero initial velocity and begins accelerating at t=0. After a short time dT, the velocity co, and yaw angle θ_{z} are given by:

ω=α_{z}dT, and θ_{z}=½α_{z}dT²(accelerometers)

These expressions are valid for a system in which both the angular velocities and angular positions are deduced by measuring accelerometer data only. If on the other hand we have a system that measures angular velocity directly using a gyroscope, the angular position is determined by:

θ_{z}=θ_{z}dT(gyroscopes).

The above expressions give the changes in ω and θ over a small time step. For digital sensors, this time step is dictated by the maximum output data rate of the sensor. A typical maximum data rate from a low cost MEMS accelerometer is 1 kHz giving a time step of dT=1 ms.

For real time motion tracking, the instantaneous accelerations/velocities are measured at one time step. These instantaneous measurements are then used to calculate the position at the next time step. If the time-stepping is done in real time (i.e. no delay between measured acceleration/velocities and calculated position), then the measured values are assumed to be constant between each measured value. This introduces errors in the measured waveform as shown in the left image of FIG. 5.

Instead of the smooth curve representing the actual arm motion, we effectively measure the stair step waveform shown in the left image of FIG. 5. This measurement error will cause subsequent errors in the calculated positions.

For periodic motions considered here, the gyroscope based system has an advantage over the accelerometer based system in that the errors in the calculated position are bounded and do not increase in time while the accelerometer system has an error that increases linearly with time as shown in right image of FIG. 5.

It should be noted that in this section, we define a real time system as one in which the motion of the system is iterated immediately as sensor data is received with no latency. This leads to the stair step waveform shown in FIG. 5 and the associated finite data rate errors. These errors can be minimized in a non-real time system where many data cycles are cached and a delayed motion calculation is presented. The errors are also minimized in postprocessing where the entire data stream is stored in memory and analyzed later. In this case a smooth curve can be fit to the data eliminating the stair-step nature. This in no way implies that a data correction scheme is not needed. For arbitrarily long time spans, any consistent sampling error in the accelerometer-only approach (as well as the gyroscope-only system as shown in the next sections) will cause the system to completely lose accuracy.

### Error Due to Constant DC Offset

While effects of data rate can be minimized by using a gyroscope-only motion tracking system, the DC offset is a serious issue for both the gyroscope-only and the accelerometer-only motion tracking systems. All real sensors can only measure a zero value to within a certain error. Part of this error is random noise in the system due to temperature, electrical noise etc. Another part of the measurement error is the constant DC offset which is present in both sensor types, which means that in the absence of motion, these sensors will still measure a small but finite value.

Therefore, any measured value of either acceleration a or rotational velocity co has the form:

α_{measured}=α_{actual}+N_{rand}+DC_{off}

ω_{measured}=ω_{actual}+N_{rand}+DC_{off}

where N_{rand} represents the random noise and DC_{off} is the DC offset. The random noise tends to average to zero over time so does not induce long term errors in the measurements. The DC offset, on the other hand, does not average to zero. This means that in any system that relies on integration of either velocities or accelerations, the calculated quantity (in this case orientation) will become inaccurate over time. For integration from accelerations we have:

θ=½αt²→θₑᵣᵣₒᵣ=DC_{off}t²

so that the error grows with the square of time and for integration from angular velocities, we have:

θ=ωt→θₑᵣᵣₒᵣ=DC_{off}t

so that the error grows linearly with time. The key point is that both single sensor systems have errors that grow unbounded with time and at some point will become completely inaccurate as a motion tracking system.

We should note that the error due to DC offset can be reduced by subtracting out the zero offset as best as possible, but it cannot be eliminated completely. The lowest measureable quantity possible in a digital sensor is dictated by the lowest bit in the Analog to Digital Converter. So, for example, using the MMA8451 from Freescale (a 14 bit accelerometer measuring acceleration on a ±2 g scale), the lowest resolvable acceleration is ˜2.4×10⁻⁴ g (where g is 9.8 m/s²). While this is a small number, it is still non-zero, and will eventually cause any long term integrations to fail.

### Sensor Saturation Due to Extremely Rapid Motions

There is one additional scenario in which the error in a single sensor system is problematic, and that is after the sensor has saturated due to extremely rapid motions. All digital sensors have a maximum detection level which is the upper bound of the sensor's measurement capability. For example, the commercially available L3G4200D gyroscope from ST Microelectronics has a maximum rotational velocity of 2000 deg/s. If the sensor is exposed to motion that exceeds this maximum value, the sensor will saturate, and the true value of rotational velocity will not be known (the system will simply return its maximum value of 2000 deg/s). It is clear that any motion tracking algorithm that is based on integrating this velocity will fail when saturation occurs.

As an example, consider again the periodic motion of FIG. 4, but assume that at one point in the run the runner stumbles. This stumble causes the runner's arms to move extremely fast (faster than maximum measureable velocity of the sensor), so that momentarily the sensor saturates. This scenario is simulated in FIG. 6.

FIG. 6 shows a simulation of the kinematical quantities of velocity and orientation of the runner. The orientation angle is integrated from the velocity according to the algorithms discussed above in this Background section. Since the gyroscope is momentarily saturated, the integrated angle is inaccurate. While this error is bounded, meaning it does not grow uncontrolled with time, it persists for all times after the saturation occurs.

In a single sensor system, this inaccuracy can only be corrected by restarting the integration from a known initial condition.

### BRIEF DESCRIPTION OF THE DRAWINGS

FIG. 1: Relates the local coordinate system to the global coordinate system, as well as to gravity and the Earth's magnetic field.

FIG. 2: Illustrates the mathematical (as opposed to physical) alignment of a sensor with the other sensors on a sensor node.

FIG. 3: Shows two accelerometers paired to measure rotational accelerations.

FIG. 4: Illustrates simulated motion of a runners arm swinging from −30 degrees to +30 degrees during a rapid sprint.

FIG. 5: Shows the finite data rate of real sensors leading to sampling error in real time tracking systems.

FIG. 6: Shows simulated position and velocity when a gyroscope saturates.

FIG. 7: Shows two segments defined on a human arm, with a sensor node located on each segment.

FIG. 8: Shows a sensor node with each of the three sensors oriented so that their local coordinate systems are physically aligned.

FIG. 9: A graph relating angular acceleration of periodic arm swings with time, and illustrating the zero crossings.

FIG. 10: Compares unbounded errors of accelerometers and gyroscopes with the bounded errors present in a three sensor system using the zero crossing error correction algorithm.

FIG. 11: Schematic showing the data transfer between a microcontroller (MCU) and the three sensor node.

FIG. 12: Schematic showing communication between the three sensors in a sensor node, a PIC MCU and an external system or device.

FIG. 13: Example printed circuit board (PCB) layout of sensor node, showing the location of the three sensors and the discrete components which are in compact 0402 surface mount packages.

FIG. 14: Schematic of a full body biomechanical suit showing the locations of sensor nodes and a central Microcontroller module.

FIG. 15: Schematic of a multiple node application where each sensor node shares common power, ground and I2C clock signals while each sensor node has a dedicated data line. The clock and data lines connect to a microcontroller unit (MCU) which reads in the sensor data for storage and/or output to external device.

FIG. 16: Illustration of the two components of the magnetic field measured by a magnetic sensor.

FIG. 17: Illustration of the calibration step required to remove the fixed magnetic field component present in measurements involving a magnetometer.

FIG. 18: Flowchart of an embodiment where the MCU and sensors are all part of the sensor node, and the MCU has embedded software which performs the orientation analysis and the zero crossing error correction algorithm.

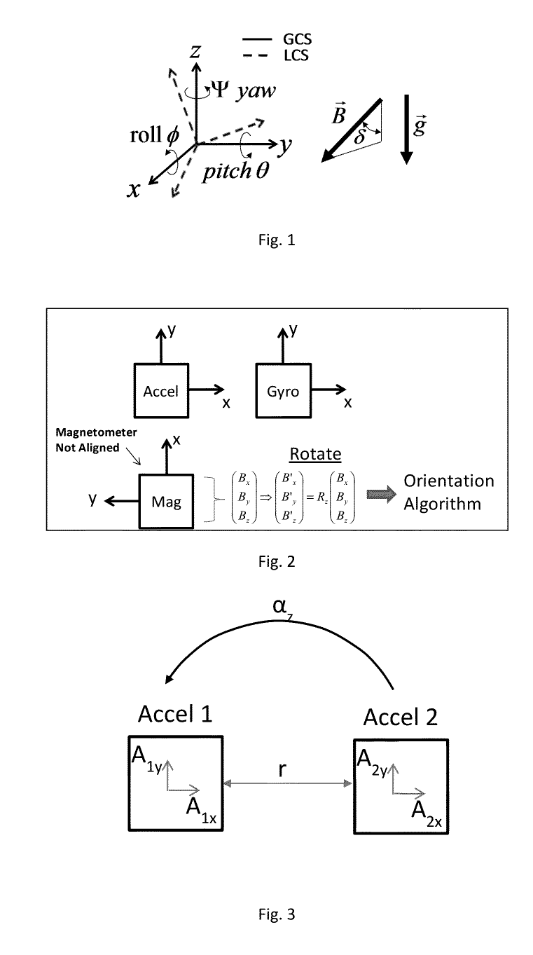

### DEFINITIONS

Error Corrected Orientation Data: This data is calculated from results of application of the Zero Crossing Error Correction Algorithm to the non-corrected orientation data. It includes the error corrected orientation angles about the x, y and z axes of the global coordinate system, also known as roll, pitch and yaw;

Global Coordinate System (GCS): A fixed coordinate system which does not move. Normally, the Z axis is in the direction of Earth's gravity, and the XY plane parallels the Earth's surface.

Graphical Representation: An image displayed on a screen or other display mechanism which shows the movement of the subject. The image may truly resemble the subject, or it may be a more simple rendering, such as a stick representation without detail, or it may show the subject with different visual characteristics, for example as an avatar.

Local Coordinate System (LCS): A coordinate system that is constant with respect to the sensor node, but which moves with respect to the GCS.

Microcontroller Unit (MCU): A small computer on a single integrated circuit containing a processor core, memory, and programmable input/output peripherals.

Periodic—an event that occurs at multiple instances in time. The interval between these time instances may be mathematically periodic (i.e. occur at a fixed frequency in time) or random and uncorrelated.

Processor: For the purposes of this application, a processor can be: (a) A multipurpose, programmable device that accepts digital data as input, processes it according to instructions stored in its memory, and provides results as output, or (b) an integrated circuit intended for specific use rather than general purpose use. Examples include, but are not limited to, an MCU, an ASIC (application specific integrated circuit), and an FPGA (field programmable gate array).

Raw Sensor Data: This is the data directly produced by the sensors. The data includes, for the accelerometer, linear acceleration along the accelerometer's local x, y and z axes; for the magnetometer, the magnetic field strength and direction along the magnetometer's local x, y and z axes; and for the gyroscope, rotational velocity about the gyroscope's local x, y and z axes.

Segments: A subject's segments are those pieces, often but not necessarily rigid lengths, which move and are attached to each other by joints, all of which pieces and joints together make up a subject. The segments and joints of a subject may be obvious, or the user of a system or method claimed herein may use independent judgment to define the segments and joints according to the user's purposes and resources.

Sensor: A microelectromechanical system (MEMS), or other very small device, which detects events or changes in quantities and provides a corresponding output. Examples are an accelerometer, magnetometer, or gyroscope.

Sensor Node: A group of sensors which are connected, which all have the same power source, and all perform measurements at the same location.

Subject: An object, person, animal, or a point on the Earth, whose movement is intended to be measured with a sensor node.

Unit: A group of things that are connected together in the same location.

Zero Crossing Error Correction Algorithm: Whenever the magnitude of the gravity subtracted accelerometer values are below a predefined threshold, the segment is in an essentially non-accelerating state. The points in time corresponding to these non-accelerating states are defined as the zero crossing of acceleration. The processor then uses the combined accelerometer and magnetometer readings of the zero crossing dataset to calculate the corrected gyroscope value, and replaces the gyroscope's actual reading with the corrected value.

### BRIEF SUMMARY OF THE INVENTION

This invention relates to motion tracking using a specific combination of sensors and an algorithm which is applied to the sensor outputs to determine sensor orientation, and correct for orientation errors that occur over time. Specifically the sensor outputs of a combination of a gyroscope, accelerometer and a magnetometer are used to accurately track motion over extended periods of time for a variety of applications, so long as the application experiences moments of zero acceleration. We use a computationally simple and accurate error correction scheme to minimize orientation errors and provide recovery from sensor saturation by innovative use of data from all three sensors. This technology has applications to sports and athletic training, the development of smart sports equipment, any handheld device, smart productivity equipment and hand tools, animation for the motion picture and computer gaming industry, 3D joysticks and peripherals for computer gaming industry, medical and health diagnosis, animal tracking and monitoring, workplace repetitive motion diagnosis as well as any other applications that track all or part of the human body.

In order to elucidate the key aspects of the technology and its utility in these applications, we first describe the human body tracking application in detail.

### Biomechanical Motion Tracking

### Orientation Through Coordinate System Tracking

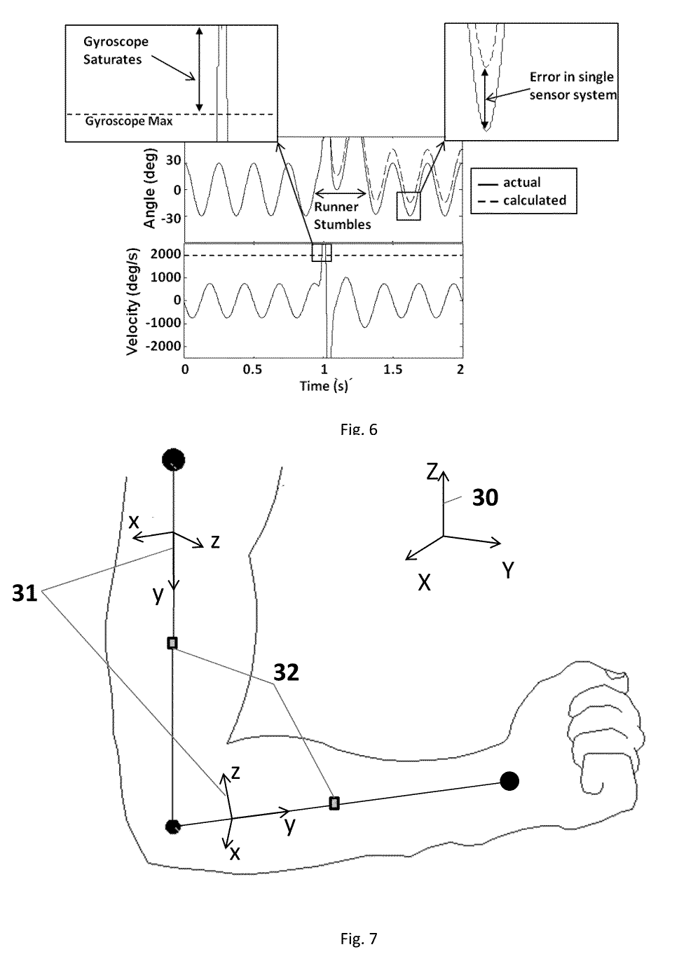

In a full body motion tracking application we attach “sensor nodes” to each independent segment in the human body. FIG. 7 shows a schematic of a human arm with two segments defined. One segment is along the upper arm and one along the forearm. To each of these segments we define a local coordinate system 31. The orientation of each local coordinate system relative to a global fixed coordinate system 30 gives the unique orientation of each of these segments. These orientations are tracked by attaching a sensor node 32 to each segment. We define a sensor node as the three sensor combination of an accelerometer, gyroscope and magnetometer, which could be discrete sensors, or a combination of sensors fabricated on a single die. These sensor nodes can be embedded in wearable clothing or strapped directly to the body using a suitable attachment mechanism. By attaching a sensor node to all segments in the body and accurately tracking the orientations of all biomechanical segments, a full body motion sensor is realized.

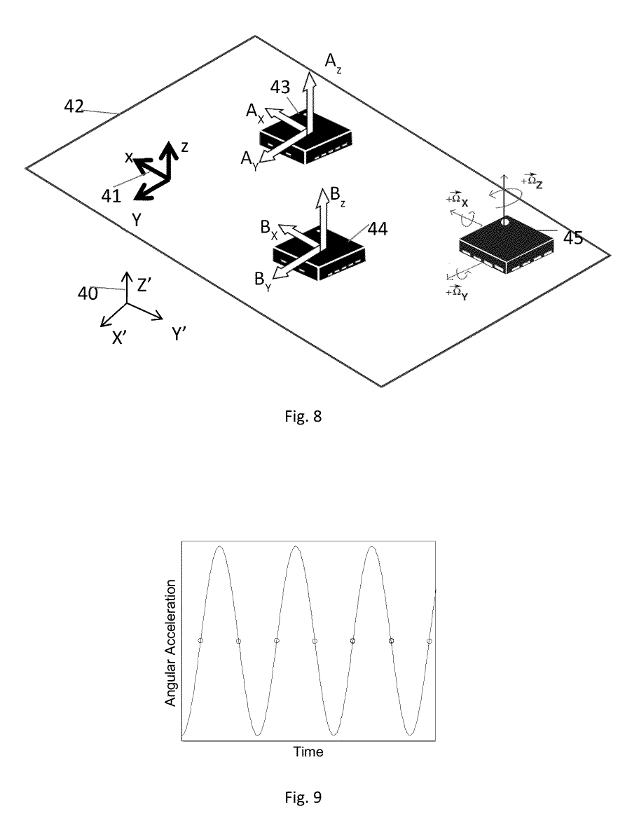

The proposed sensor node 42 pictured in FIG. 8 consists of three sensors. Each of the sensors is oriented so that their local coordinate systems are aligned. The magnetic sensor 44 is used to locate the Earth's geomagnetic field, B, the accelerometer 43 (in the absence of external accelerations) measures the Earth's gravitational field, g and the gyroscope 45 measures the angular rotations. The sensor node 42 is fabricated so that each of the three sensors has its axis aligned along a common local coordinate system 41 as shown in FIG. 8. The global coordinate system 40 is also shown in FIG. 8.

Having the sensor axes aligned is not absolutely critical for the orientation algorithm, but does simplify the ensuing math, which is described above in the Background section.

### Advantages of Proposed Technology

### Key Advantage

The key to this innovation is the ability to minimize orientation errors and provide recovery from sensor saturation by innovative use of data from all three sensors. We use the gyroscope to measure the rotational velocities of each segment and deduce the angular orientations through integration. Using the combination of accelerometer and magnetometer, we are then able to apply a simple algorithm to systematically correct for any error in the calculated orientations due to data rate and DC offset, as well as provide a means to accurately recover from sensor saturation. With these advantages, this three sensor motion tracking and error correction technique is more accurate and robust than competing technologies.

### Error Correction Using Zero Crossings of Acceleration

The Background section has detailed three sources of error that make orientation tracking with sensors problematic. The key to this innovation is the ability to self-correct and minimize these errors by identifying points in the motion where the acceleration is zero, and exploiting the accelerometer's ability to determine the direction of gravity at these points.

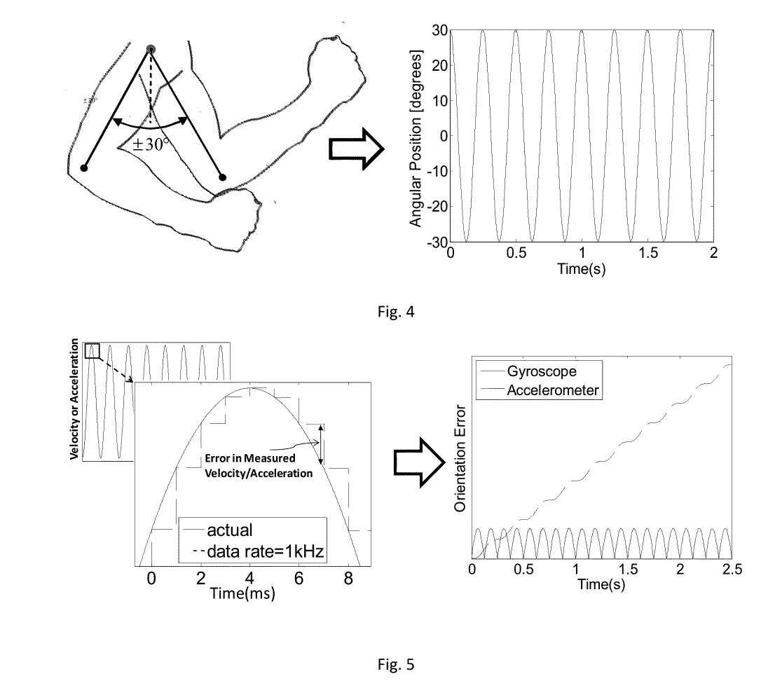

To illustrate this concept, consider again the motion in FIG. 4. The acceleration curve for this motion is shown in FIG. 9.

The zero crossings of the acceleration are shown with circles. At each of these points in the motion, the accelerometer measures the direction of gravity and, using the equations in the Background section, the orientation is calculated exactly when combined with the magnetometer data. In this way, the error of the three sensor system is always bounded and never grows uncontrolled with time.

The method of zero crossing self correcting orientation in a moving device is described in more detail as:

1) Using the accelerometer's measurement at its zero crossing point, to obtain the Earth's gravitational field direction ‘g’;

2) Using the magnetometer at the acceleration zero crossing point to obtain the Earth's magnetic field direction ‘B’

3) Using the directions of B and g to calculate the true orientation of the sensor node relative to a fixed space coordinate system; and

4) Using this true orientation to correct for any errors in the dynamically calculated orientation obtained from the gyroscopes.

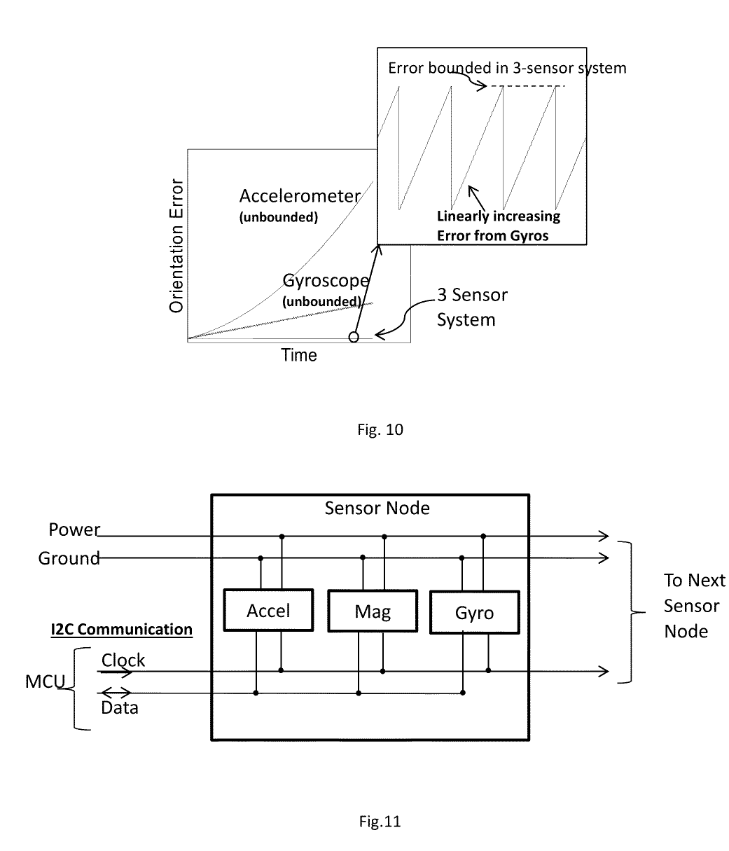

We can now compare the error in the three sensor system with the gyroscope and accelerometer systems including the errors from both finite data rate and DC offset. We assume that the orientation angles in the three sensor system are obtained by integration of the gyroscope sensor data. The results are shown in FIG. 10.

As can be seen in the figure, both the accelerometer and gyroscope based motion tracking systems completely lose accuracy over extended time periods. The presented motion tracking system does not and is expected to be far more accurate at tracking orientations over extended time periods.

FIG. 10 shows the mitigation of errors from the finite data rate and the DC offset. The error due to momentary saturation is also mitigated using this zero crossing error correction strategy. FIG. 6 shows that the error due to momentary sensor saturation persists for all times after the saturation occurs. In our three sensor motion tracking system however, the inaccuracies are corrected the next time the runner's arm goes through a point where the acceleration is zero, by employing our error correction technique. Again we see that the ability to systematically self-correct provides a key advantage of this technology over existing solutions.

### DETAILED DESCRIPTION OF THE INVENTION

The sensor node for our motion tracking system requires three sensors: an accelerometer, a magnetometer and a gyroscope. Each of these sensors measures and outputs data at a fixed data rate. The data from each sensor is read using a central Microcontroller Unit (MCU). The simplest architecture for the sensor node is that which only contains the three sensors and the associated discrete components needed for most commercially available MEMS sensors. In a complete system, however, in addition to the MCU, we would use suitable data storage (e.g. flash memory), and data transmission devices such as RF transmitter etc. In the descriptions to follow we distinguish between the sensor nodes (the three sensor combination of Accelerometer, Gyroscope and Magnetometer) and the MCU module which contains all other devices to make a complete motion tracking system. For multi-sensor node systems such as the bio-suit, this is the most logical architecture. However, for single sensor node applications, it is understood that all sensors, external interface devices, and MCU may be on a single physical board.

In discussing the communication between the various sensors and the MCU, we make a distinction between two types of communication. The first is communication between the MCU and sensors in one or more sensor nodes. The second is that between the MCU and any external devices, such as a computer or smartphone. The microcontroller communicates with the sensors via the I2C (Inter-Integrated Circuit), SPI (Serial Peripheral Interface), or similar communication protocol. This communication from sensor to MCU is dictated by the sensor manufacturer. The communication from MCU to the outside world may be chosen based on the particular application

### Communication Between MCU and Sensors

For concreteness we will consider the communication from MCU to sensor using the I2C protocol as shown in FIG. 11.

A single sensor node requires only four external wires to operate: Vcc (power), ground, an I2C clock and an I2C data line. In the I2C protocol the data line is bi-directional and each listening device (e.g. one of the sensors) has a unique physical address. The MCU talks to the device by first sending this unique address out on the data line. Once the device has been addressed (and only when it is addressed) it sends its sensor readings back to the MCU at a rate determined by the clock speed which is controlled by the MCU. Standard I2C clock frequencies are 100 Kbits/s (standard) and 400 Kbits/s (fast mode). All sensors in this design are capable of running in the fast I2C mode which allows for up to 50,000 bytes of data per second to be transferred. This fast data rate is important for multi-node applications in which fine resolution of rapid motions may be involved.

### Communication Between MCU and External Devices

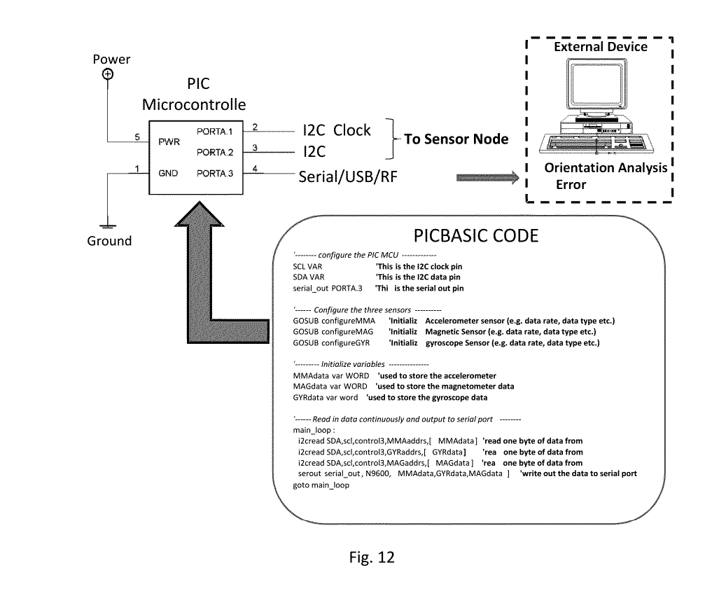

A low cost microcontroller such as the PIC line of controllers from Microchip Inc. is used to interface with the sensor node. The PIC controllers have configurable I/O pins and can be programmed with the easy to use PIC basic programming language. FIG. 12 shows a simplified PIC MCU configuration along with the relevant sections of PIC BASIC code needed to interface with the three sensor node.

The embedded PIC microcontroller is used to continually receive data from the sensor node as quickly as possible and send that data out to an external system or device such as a standalone PC, smartphone, USB device, RF transmitter or other external device. The communication protocol used to send out data from the MCU to an external device may consist of any wireless protocol such as Bluetooth, Wi-Fi or any other RF method. It may also consist of any wired protocol such as USB, Firewire, or serial port. The external device will then perform the orientation analysis outlined above in Background, and the zero crossing error correction scheme outlined in this section, Detailed Description of the Invention.

Another embodiment is for the sensor node to be incorporated within the system or device performing the orientation analysis and zero crossing error correction algorithm. Examples of this would be incorporating the sensor node into a smartphone, which would then perform the orientation analysis and zero crossing error correction algorithm locally.

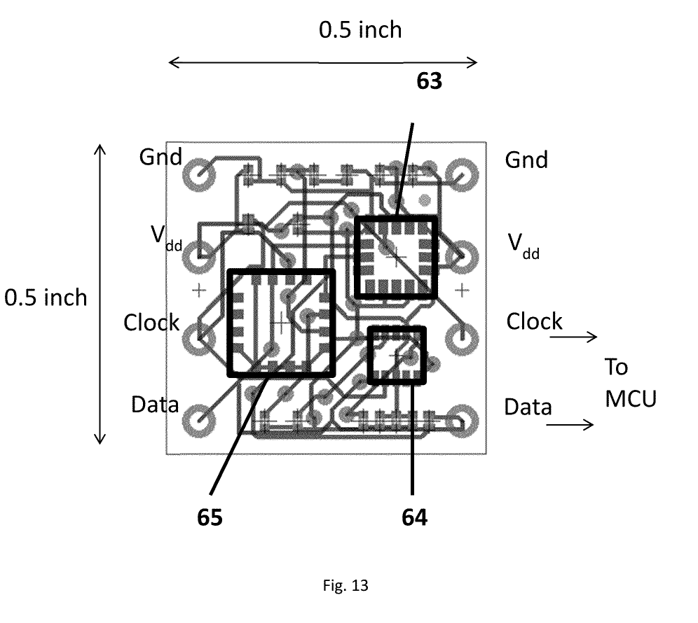

The physical fabrication of the three sensor node can be standard Printed Circuit Board (PCB) technology. A PCB layout of the three sensor node is shown in FIG. 13.

This layout includes all three sensors and all necessary discrete components (resistors and capacitors) for proper operation of the sensors. The sensors in this realization are:

1) Freescale MMA8452 (Accelerometer) 63

2) Freescale MAG3110 (Magnetometer) 64

3) ST Microelectronics L3G4200D (Gyroscope).65

The discrete components are each in a compact surface mount 0402 package. It is clear that many other physical layouts of these components are possible but this shows the compactness possible in this type of three sensor node. In this example, the entire sensor node is accommodated on a small 0.5 in square circuit board using 6 mil wide traces which can be readily printed at commercial board houses. Additionally, many manufacturers are moving towards integrating different types of inertial sensors (e.g. accelerometer and gyroscope) all on a single die. In this case the physical layout of the three sensor (single IC) node would be even more compact which could be important for the aesthetics of wearable sensor nodes.

### Description of Biomechanical Suit

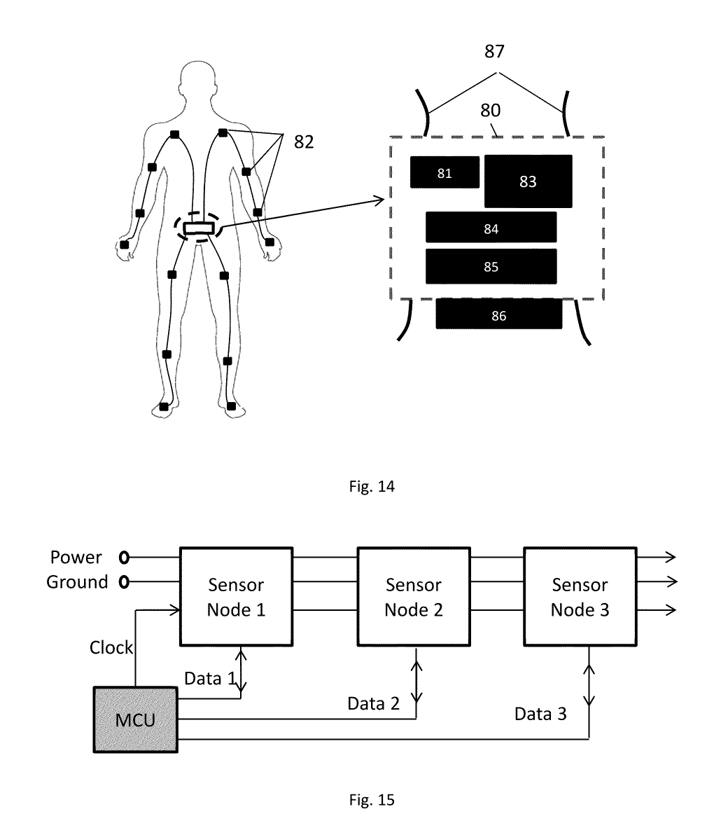

For the biomechanical suit application, multiple sensor nodes are embedded in a wearable tight fitting material such as the compression suits found in athletic apparel stores. For a full body biomechanical suit, at least one sensor node is needed for each moving body segment of interest. The sensors are fixed to the surface of the fabric using either fabric glue or sewing directly into the material. The approximate sensor node locations for a full body biomechanical suit and the associated power and I/O accessories are shown in FIG. 14.

The figure shows multiple sensor nodes 82 connected electrically to a central MCU module 80 located along the beltline. The MCU module 80 contains any necessary electronics for power, memory storage, data transmission and peripheral connectivity. The embodiment in the figure consists of a PIC microcontroller 84 which is paired with a flash memory module 83 to store the sensor data and a means to read out the data to an external system (or device) such as serial Port, USB port 86 and/or wireless transmitter 85. A battery 81 provides power to all components.

The electrical connections 87 between the sensor nodes and the MCU module are made using a suitable insulated thin conductor such as magnet wire. Magnet wire is a highly flexible very thin gauge of wire with diameter as small as a few mils. This wire is insulated with a thin layer of nonconductive material (e.g. mylar) and is thin enough that it can be used as sewing thread.

In a different embodiment, each sensor node in this configuration could be made independently wireless (e.g. with an integrated RF transmitter integrated within the node) so that no physical wires are used to connect different nodes to the MCU module.

In the case of using a physical wired connection, this conductive “thread” will be stitched into the compression suit using suitable wiring patterns (such as a zigzag pattern) that preserve the flexibility of the material while providing a robust electrical connection between nodes and the MCU module.

In principle, the more sensor nodes contained in the bio-suit, the more electrical wires are needed to connect between sensor nodes. In these multiple sensor node applications however, the power, ground and clock lines are connected serially through each device and only the data line is unique to each sensor node as shown in FIG. 15.

This greatly simplifies the wiring of a multiple sensor node system since only one dedicated line per node is required and three common lines run through the complete system. The clock and data lines connect to an MCU, which reads in the sensor data for storage and/or output to an external device.

### Zero Crossing Error Correction Algorithm

Referring again to FIG. 9, the zero crossings of the acceleration are shown with circles. At each of these points in the motion, the accelerometer measures the direction of gravity. It is at these points that the zero crossing error correction algorithm is implemented.

Our error correction uses the gyroscope data during times when accelerations are present. The 3D gyroscope outputs data at discrete time intervals dT (the time interval dT is dictated by the output data rate of the sensor). This gives a running series of discrete data points at fixed time intervals. Denote the discrete time points as tᵢ where the index i takes the values i=0, 1, 2 etc. At time tᵢ the gyroscope outputs the three axis rotational velocities (ω_{x,i}, ω_{y,i}, ω_{z,i}). The instantaneous orientation angles are calculated by performing a discrete time integral on the angular velocities. Specifically the three orientation angles at time tᵢ are given by: θ_{x,i}=θ_{x,i-1}+ω_{x,i}dT, θ_{y,i}=θ_{y,i-1}+ω_{y,i}dT, and θ_{z,i}=θ_{z,i-1}+ω_{z,i}dT. Here θ_{x,i-1}, θ_{y,i-1}, θ_{z,i-1}) are the orientation angles at the prior time step tᵢ₋₁ and tᵢ=tᵢ₋₁+dT. We will refer to this as the time stepping routine. The steps for error correction are now as follows:

1) During normal operation when accelerations are present, the instantaneous orientation angles at time tᵢ are calculated from the gyroscope data using the time stepping routine described above.

2) At points in time in which the magnitude of the acceleration is below a predefined threshold, and thus defined to be zero, the accelerometer and magnetometer data are combined using the equations in the Background section, to calculate the orientation angles independent of the gyroscope data. These are considered to be the exact value of the orientation angles and are in principle more accurate than the gyroscope integrations. Denote these values as (θ_{x,exact}, θ_{y,exact}, θ_{z,exact}).

3) The error correction is implemented at the zero acceleration points by replacing the gyroscope-derived value of the orientation angles with the exact values. Explicitly we set θ_{x,i}=θ_{x,exact}, θ_{y,i}=θ_{y,exact}, and θ_{z,i}=θ_{z,exact}) and continue with the time stepping routine at step one above. In this way, the error of the three sensor system is always bounded and never grows uncontrolled with time so long as the motion goes through points where acceleration is zero.

This self correcting capability allows the sensor node to mitigate the errors caused by the finite data rate and constant DC offset inherent in all sensors as well as the effects of sensor saturation in rapid motion scenarios. Additionally the computationally simple zero crossing error correction algorithm is ideal in embedded applications where extended battery life is desired. Finally for systems in which the sensor data is transferred to an external processor, the simple error correction scheme minimizes the amount of data that must be transferred. Only the gyroscope data is transferred typically, while the accelerometer and magnetometer data need be transferred only at the zero crossings. This is especially important for wireless data transmission at high data rates.

This increased accuracy and computationally simple error correction scheme gives this three sensor node motion tracking system an advantage over other techniques, and has applications to many areas including sports, the motion picture industry, the computer gaming industry, robotics, and health care and diagnostics.

### Technique/Algorithm for Use with Ferrous Materials

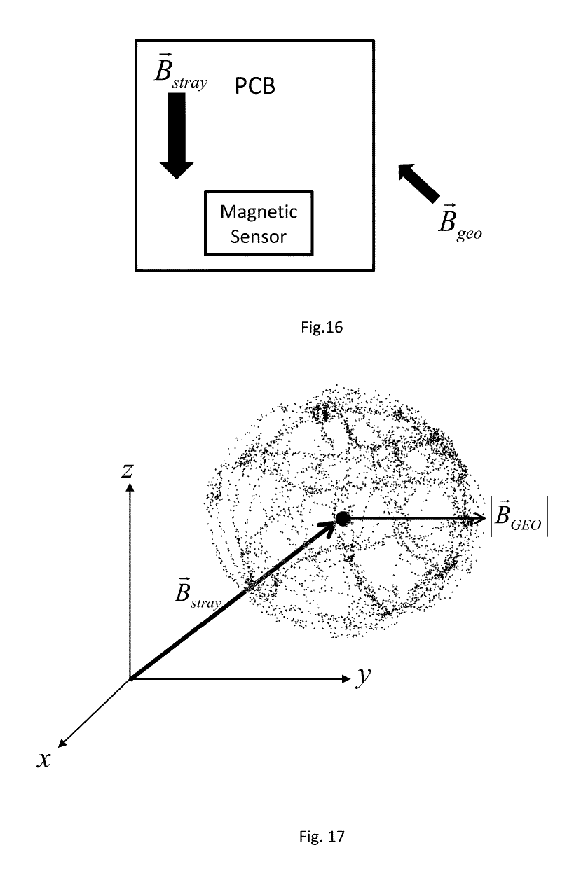

The use of magnetometers to sense the direction of the Earth's magnetic field, \vec{B}_{geo} is complicated by the fact that metal or ferrous materials in close proximity to the magnetometer may produce magnetic fields that are much greater in magnitude than the geomagnetic field. For instance, after mounting the magnetometer to a printed circuit board (PCB), a stray field, \vec{B}_{stray}, is produced from all the other components on the board. This situation is illustrated in FIG. 16. This stray field complicates the orientation algorithm which requires that the magnetometer measure the direction of magnetic north. This stray field is always measured to have a constant value relative to the magnetometer. The usual method for dealing with this is to subtract off the stray field so that only the true geomagnetic field is left. In practice, this requires a calibration step to be performed after the magnetometer has been mounted on the PCB.

For small PCB's, the calibration step involves rotating the PCB through all rotation angles and continually logging the field measured by the magnetometer at each rotation point. The data obtained from this type of calibration is shown in FIG. 17.

Each dot in FIG. 17 is data taken from a commercial magnetometer as it is rotated around its origin. The locus of data points from the true geomagnetic field forms a sphere. The key is that the stray field is fixed to the PCB and measures a constant value on the magnetometer independent of rotation. The result of the measurements is a sphere of data points that is offset from the origin. The vector from the origin to the center of the sphere, \vec{B}_{stray}, represents the stray field. This method is a simple way to determine the stray field and only needs to be performed once after the magnetometer has been fixed to its PCB. Once the vector \vec{B}_{stray} is determined, it may be subtracted from all future measurements so that only \vec{B}_{geo} is left.

The assumption is that this stray field is truly fixed and does not change with time. This means that the sensor node cannot be used near any objects that carry a magnetic field such as metal or ferrous objects since they will add an additional field component, \vec{B}_{ferrous}, which has not been calibrated out. In principle a new calibration can be obtained by completing the rotations again after the sensor node has been attached to the ferrous object, but this is cumbersome and in some cases impractical.

An example would be using sensor nodes for large construction projects in the construction industry. In this application, a sensor node would be placed on each beam during construction to measure its orientation and location. This data would be periodically transmitted to an external platform where it could be correlated with a CAD model of the architectural design to insure accuracy and give the designer a real-time update on the progress of construction. For physically large beams it is impractical to perform a rotation calibration step so that an alternative calibration method is needed.

In the three sensor architecture proposed herein, the gyroscope is used in conjunction with the magnetometer to remove stray fields from the magnetic measurements without the need for multiple rotation calibration steps. The following sequence defines this new calibration method using the three sensor node in applications involving ferrous objects.

1) The magnetometer is mounted to a PCB and the stray fields from the PCB components are properly calibrated and zeroed using the standard rotation method described above.

2) The vector representing the true geomagnetic field is now obtained. This is stored as the initial orientation of the geomagnetic field \vec{B}_{geo,initial}.

3) The gyroscope is now used to track the pitch, roll, and yaw rotations (θ, φ, ψ) of the PCB using the integration methods described in the kinematical equations presented in the Background section above. Since \vec{B}_{geo} is fixed in space, its orientation relative to the local coordinates of the rotated PCB is readily determined from the roll, pitch and yaw angles as \vec{B}_{geo}=Rₓ(φ)R_{y}(θ)R_{z}(ψ)B_{geo,initial}, where R_{x,y,z} are the three dimensional rotation matrices. This provides a method to track the orientation of \vec{B}_{geo} in the local coordinates of the sensor node using only the data from the gyroscope, independent of the magnetometer readings.

As the node is brought into close proximity to the ferrous object, the magnetometer will begin to measure the field associated with the ferrous material along with the true geomagnetic field, and once the node is in place, the magnetometer measures the vector sum: \vec{B}ₜₒₜₐₗ=\vec{B}_{geo}+\vec{B}_{ferrous}. At this point the magnetic readings cannot be used to get \vec{B}_{geo}. The key to this innovative calibration method is that the true orientation of \vec{B}_{geo} is obtained from the gyroscope rotation information (step 3). This allows the component \vec{B}_{ferrous} to be computed (\vec{B}_{ferrous}=\vec{B}ₜₒₜₐₗ−\vec{B}_{geo}) and subtracted from any future magnetic field measurements.

It should be noted that magnetic fields fall off rapidly with distance (i.e. they fall off with 1/r³ from the source), so that only the ferrous components that are in close proximity to the sensors will affect the magnetometer readings.

This calibration routine is in some sense the complement of the error correction scheme outlined in previous sections. In that case, the magnetic sensor was used (in conjunction with the accelerometer) to correct for errors in the gyroscope data. In this calibration method, the gyroscope is used to correct for errors in the magnetometer data showing again the utility of the three sensor method over competing single sensor technologies.

### Alternate Configurations

Our invention consists of use of a three sensor node that provides the data needed for the described node orientation and orientation zero crossing error correction, useful for a myriad of motion tracking applications. The sensor node consists of a combination of gyroscope, accelerometer and magnetometer and is more accurate in motion tracking applications than existing solutions which involve only a single sensor. The proposed system tracks motion using a gyroscope and uses an algorithm to calculate the orientation of objects and to periodically self correct any errors induced in the calculated angular position. A simple configuration has been described. We consider other configurations to also be within our invention, as follows.

Sensor Nodes can incorporate the MCU, battery, and means to communicate to an external system (wirelessly or otherwise) directly onto the node.

Sensor Nodes can incorporate a battery, and wireless capability, to communicate to an MCU located somewhere on the ‘suit’ (i.e., elsewhere on the system).

Sensor Nodes can incorporate the MCU, battery, and the ‘external device’ all in one package, and where the orientation and orientation correction algorithms are performed within the same package (examples include PDAs, smart phone, or other handheld device).

Sensor Nodes can incorporate alternate hardware configurations, including but not limited to alternate communications protocols and sensor devices.

Motion tracking may be performed where more than one sensor node is attached to a segment, for improved accuracy through averaging the outputs.

Sensor nodes may be attached to subjects or segments of subjects using physical attachment mechanisms including but not limited to tape, hook and loop fasteners, suction cups or glue.

Appropriate MCU's may be obtained from any manufacturer and be of a type other than the PIC microcontroller described. MCU's may have embedded code written in programming languages other than PICBASIC.

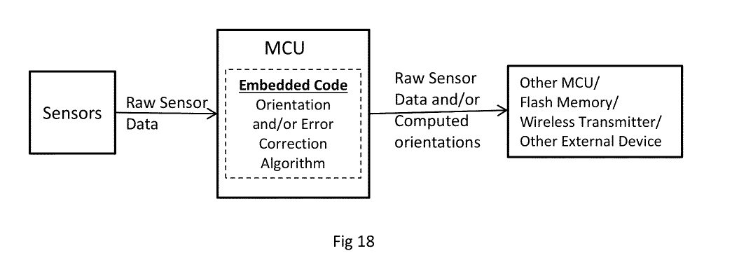

Sensor nodes can incorporate the MCU, where the orientation and/or zero crossing error correction algorithm are embedded within the MCU. In this embodiment, the MCU performs all or a portion of the orientation analysis and error correction and either stores this data in a suitable local memory module or transmits the data via wired or wireless means to another MCU or other external device. FIG. 18 flowcharts an embodiment in which (a) the MCU and the sensors are part of the same node, and (b) the orientation analysis and zero crossing error correction scheme are implemented in embedded software within the MCU. The MCU takes the raw data from the three sensors (magnetometer, accelerometer and gyroscope) and performs all or a portion of the orientation and error correction computations. The MCU then stores to a memory module and/or transmits via wired or wireless means the set of computed orientations and/or raw data to an external memory module, another MCU, or an external device. The data transmitted may be all or a subset of the orientation and raw sensor output data sets.

Embodiments in which multiple sensors of the same type are included in a single node to improve resolution—In this embodiment, the fixed data rate of a single sensor is increased through redundancy. If a single sensor has a maximum output data rate given by ODRₘₐₓ then two sensors has an effective maximum data rate of 2*ODRₘₐₓ. For very rapid motions, the maximum sampling rate of a single sensor may be too slow to capture the fine details of the rapidly varying velocities. In this embodiment, we overcome this shortcoming by adding multiple sensors of the same type (e.g. two or more accelerometers, gyroscopes, and/or magnetometers) to the same node. We improve resolution by offsetting the sampling time of each duplicate sensor by a known amount from other sensor(s) of the same type. This offset may be accomplished by initiating the data acquisition sequence in each sensor at slightly different times. The offset in the start time of the sensor data acquisition would correspond to the offset required in the data sampling. Furthermore, to additionally increase data collection and processing capabilities, we may include multiple MCU's in a single node. In order to minimize post processing alignment between sensors of the same type, it is ideal to orient each similar sensor to each other, minimizing alignment errors.

Sensor nodes can include means for wireless transmission AND wireless reception (i.e. an RF transmitter and receiver on one node). Some benefits of this embodiment include (a) allowing for coordinated data transfers thus preventing multiple nodes from transmitting simultaneously, and (b) providing a means to communicate with sensor nodes for ‘node provisioning’ schemes discussed below

Sensor nodes can incorporate a GPS device. This would allow for location accuracy over large areas as well as orientation accuracy.

### Data Transmission and Data Storage Embodiments

The output data rate (ODR) of the sensors can be implemented to vary based on the rate of change of the orientations. In this embodiment, the MCU retrieves data from the sensors at a reduced rate for slow motions, and may also instruct the sensors to capture data at a reduced ODR for slow motions. This reduces the amount of data needed for proper analysis and reduces power consumption.

The raw data and/or computed orientations can be transmitted at a variable data rate to ensure accurate integrations. In this embodiment, the MCU transmits data at a variable data rate depending on the accelerations involved. For rapidly changing velocities (i.e. high accelerations) both the integration routines and any real time display require velocity measurements over small time steps, while slowly varying motions can be integrated and displayed with larger time steps. This embodiment uses a smart algorithm to determine the proper transmission rate to ensure accurate motion analysis as well as a smooth transition for a real time display.

The raw data and/or computed orientations can be transmitted at a variable data rate to ensure a smooth real-time graphical display. In this embodiment, the MCU again transmits data at a variable data rate depending on the accelerations involved. As an example, video data is refreshed (updated) at a fixed frame rate (approximately 30 frames per second). This frame rate may be unnecessarily high for slowly changing motions and too slow for slow motion playback of rapid motions. This embodiment would use a smart algorithm to determine the proper transmission rate to ensure a smooth motion for a real-time display.

A reduced or compressed data set can be stored in local memory. In this embodiment, the data is analyzed within the MCU to determine if the entire data stream is needed for computing and/or displaying the orientations. If a smaller subset of data can be used to compute and display the orientation changes, then only that subset is stored. This embodiment includes schemes for data compression as well as eliminating redundant or useless data packets (e.g. for static situations where the orientations do not change, only the first data sample is needed, and new data is stored only when motion resumes).

### System Level Embodiment Clarifications and Additions

Full body or partial body biomechanical applications that incorporate multiple sensor nodes can be independently wireless. In this embodiment, multiple sensor nodes are attached to various segments of the human body, and each node has an independent wireless transmitter. This embodiment eliminates the need for any wired connections between nodes. This embodiment may entail having the wireless sensor nodes embedded in wearable clothing, externally attached to wearable clothing (e.g. using hook and loop fasteners), or this may entail attaching nodes directly to the body (e.g. using tape or straps).

Node Provisioning and Mapping—

For multi-node systems with nodes that transmit independently (i.e. a system with multiple nodes that each contain a wireless transmitter), a suitable protocol is used to uniquely identify the source of each set of sensor/orientation data. This can involve assigning a unique serial number or identifier to each node and having the sensor node transmit this identifier along with each set of sensor raw data and/or orientation data. Furthermore, it is necessary to know where each node is relative to other nodes in the system. As a result, a means of identifying and storing the location of each node relative to other nodes is required. Identifying location may be accomplished by a number of methods, including, but not limited to the following: (a) knowing the general independent segments within the system and their general range of motion, and determining through the use of a ‘smart’ algorithm the feasible location of each sensor within the system, given motion constraints of the segments within the system; (b) pre-identifying sensor nodes as targeted for a specific location within the system, and then incorporating sensor nodes with the appropriate location pre-identification into that location on the system; (c) prior knowledge of system architecture, and assignment of nodes with unique IDs to locations within the system architecture, thus generating a relationship between system segments and sensor node IDs; (d) adding GPS capability to a node and transmitting the GPS location information; and (e) using a physical scanning device that requests each of the sensor nodes to transmit its ID, and as the scanning device passes over the system, the sensor node with the highest transmitting signal strength is determined to be at that location. Storage of the system's node map may occur on any or multiple memory modules within the system, or even in an external device for use with the system.

Multiple Systems Operating Concurrently (Multi-Body Problem)—

This system level embodiment involves multiple subjects, each of which may contain multiple sensor nodes. An example is a system that tracks the orientation of an entire sports team simultaneously, where each player represents a subject, consisting of multiple sensor nodes. In this case, for each subject, a tiered system of nodes may be employed which includes one or more master or primary nodes in addition to the regular or secondary sensor nodes. Some of the primary node characteristics may include:

1) Primary node has a unique identifier, allowing a monitoring system (external system), to identify it as unique from other subjects being monitored/recorded.

2) Primary node can also store the ‘map’ (locations) of each of the secondary sensor nodes within the system.

3) Primary node can serve as local ‘repository,’ including receiver to read data transmissions from each sensor node, and allowing each of the sensor nodes to remain small in size and eliminating need for local memory content of each sensor node.

4) Primary node can incorporate GPS, for locating the subject and for understanding position relative to other subjects.

5) Different nodes may incorporate a higher power or different type of transmitter. For example, the regular sensor nodes may contain low power short range transmitters such as Bluetooth, while the master node may contain hardware for cellular communication.

6) Master node may collect and/or calculate orientation data from each secondary sensor node, and transmit in packets to external system or cellular network.

7) Master node may include larger memory capacity than secondary sensor nodes.

### High Level Applications and Embodiments

A detailed description of our motion tracking system consisting of a sensor node with three sensors, an MCU module and application of the zero crossing error correction algorithm, and use of the system in a full body biomechanical suit has been described. The described motion tracking technology is not limited to this application however. Other embodiments and applications of this technology include, but are not limited to those described below.

Motion Picture Animation—

In this application, the true motions of actors wearing sensor nodes are recorded. This motion is then re-rendered in software to produce animation such as that used in the movie Avatar.

Gaming Industry—3D Mouse or Gaming Controller—

In this embodiment, a single sensor node provides complete orientation of the mouse/controller for interactive games.

Gaming Industry—Body Suit for Gaming Industry—

In this application wearable sensors are attached to game players to measure body motions for real-time incorporation into action-type games.

Sports Equipment—Embedded Sensors in a Ball/Projectile—

A sensor node is embedded within a piece of sports equipment that is used as a projectile. For example, a sensor node embedded internally within a football would provide feedback as to the rate of rotation of the spiral as well as trajectory.

Sports Equipment—Embedded Sensor in Lever Type Sports Equipment—

A sensor node would be attached to a golf club, baseball bat or other sports equipment to give feedback on the swing dynamics.

Sports Equipment—Sports Gear—

In addition to the full body suit, sensor nodes could be embedded in shirts, shorts, gloves, jerseys, or shoes, or other forms of clothing, providing feedback on orientation, acceleration, velocity, and location of various body parts in training, or in game situations.

Smart Productivity Equipment and Hand Tools—Smart Measuring Tape—

This embodiment uses sensor nodes to calculate distance traveled (length). No need for physical tape, just a digital readout.

Smart Productivity Equipment and Hand Tools—Smart Pen—

This embodiment uses an embedded sensor node with memory and an MCU module to track motion of pen's head, recording and later recreating pen strokes when downloaded to an application, or transmitting sensor data to an external MCU, and to an external device for real time orientation interpretation.

Smart Productivity Equipment and Hand Tools—Smart ‘Laser’ Pointer—

This embodiment uses an embedded sensor node and an MCU module to track the motion of a ‘pointer’, which transmits the sensor node's motion to a computer which interprets movements and updates the location of the pointer on a display.

Smart Productivity Equipment and Hand Tools—Smart Ax—

In this embodiment, a sensor node attached to or embedded within an ax monitors trajectory and orientation of the ax as it strikes a target, helping to identify inefficiencies in stroke or targeting.

Medical Diagnostics/Therapy—Chiropractic—

In this embodiment, sensor nodes are attached to specific parts of the body to track a user's posture and gait after injury or during an extended chiropractic therapy. The sensor nodes measure and record the subject's biomechanics, which are studied by a health professional, and improvements to a patient's posture and mechanics are made based on these readings.

Medical Diagnostics/Therapy—Infant Breathing/SIDS (Sudden Infant Death Syndrome) Monitor—

In this embodiment, a sensor node attached to the torso of an infant provides feedback on proper breathing during sleep, and may be used to detect when a baby has stopped breathing. This would serve as a SIDS prevention device.

Medical Diagnostics/Therapy—Sleep Apnea—

In this embodiment, a sensor node attached to an adult's torso provides feedback as to breathing rate, sleeping position, and chest displacement when breathing. By tracking breathing patterns during sleep, a health professional may recommend ways to alleviate sleep disorders.

Productivity—Factory Workers—

In this embodiment, sensor nodes on wrists, arms, and/or legs of workers (or clothing) would track the motions that workers perform to do their jobs, helping to identify the most efficient means of accomplishing certain tasks, as well as potentially identifying the most productive workers, times of day, and shifts, for example. Tracking worker movement could also be used to identify inefficient or labor-intensive processes or product lines.

Productivity—Line Workers—

In this embodiment, sensor nodes record the biomechanics of workers over time. In the event of workplace-related injuries, sensor data is used to determine if repetitive motions were a contributing factor.

Productivity—Carpal Tunnel Syndrome and Related Repetitive Motion Injuries—

In this embodiment, sensor nodes on the wrist and forearm help diagnose repetitive injuries from carpal tunnel syndrome or similar conditions for office workers or others who use keyboards for long periods of time.

Productivity—Office Place Posture—

In this embodiment, sensor nodes are attached to or embedded within adjustable office furniture to measure the seated posture of office workers suffering from back/neck pain. This data is then used to better recommend seating settings for adjustable office furniture.

Productivity—Package and Inventory Tracking—

In this embodiment, sensor nodes are embedded on packages for shipment, or on inventory items handled by machines or people, for the purpose of tracking the position, orientation, and forces applied to packages/inventory over time, to monitor proper handling and care procedures.

Construction Industry—

In this embodiment, a sensor node is attached to each physical beam or section of a building or other structure during construction. The orientation of each sensor node relative to the beam or section to which it is attached must be known and noted. The orientation of each beam may then be correlated with the architectural design to ensure proper construction. In addition to orientation information, GPS may be added to the node to provide both orientation and location of the beam, and this orientation/location information is transmitted using wireless or wired means to external devices. This application requires that each relevant sensor node be associated with the physical beam/structure to which it is attached. This association of sensor node to physical item may be done in several ways including but not limited to the following:

The physical dimensions of the beam/structure to which the node is attached may be transmitted along with the orientation and GPS location information.

A unique ID which identifies a particular part in a CAD model may be transmitted along with the orientation and GPS location information. This allows the physical dimensions of the beam/structure to be inferred from the CAD model of the construction.

A generic serial number, unique to each node is transmitted in addition to the orientation/location information. This requires that a log or record be kept of which serial number was attached to a particular physical beam or structure. This would again allow the physical dimensions of the beam/structure to be inferred without the node needing to transmit this information. This application can provide real time feedback to the architect/designer that all sections of the construction project are being assembled properly, potentially eliminating construction errors and streamlining the construction process. This data may also be used by city inspectors to ensure that proper construction techniques were used.

Military Training Exercises Over Large Areas—

This embodiment involves a system of systems with master (or primary) and secondary nodes, similar to the application described for a sports team, and summarized below:

1) Each primary node may include GPS, RF receiver/transmitter, and/or long range communication hardware such as cellular for transmitting to another external system.

2) Each secondary sensor node includes short-range low-power transmitters such as bluetooth or RF transmitters for communication to/from the primary node(s).

3) Each primary node collects or calculates orientation data from each secondary sensor node, and transmits in packets to external system.

Applications in which the accelerometer provides linear motion data in addition to the orientation analysis data—Accelerometers measure linear as opposed to rotational motions. This linear acceleration may be used to calculate information regarding the center of mass motion of a node. If used in conjunction with GPS, this may provide a highly accurate system which measures both orientation and motion for each sensor node over wide areas and for long time spans.

1. A system for tracking motion and calculating error corrected orientations, comprising:
A sensor node, which comprises an accelerometer, gyroscope and magnetometer, and which is attached to a segment of a subject that is expected to move;
Means for instantaneous raw sensor data to pass from the sensor node to a microcontroller unit (MCU);
An MCU which receives raw sensor data from the sensor nodes;
Means for performing data processing and/or analysis on the sensor data, computing the orientation of the sensor node as well as for applying the zero crossing error correction algorithm to the computed orientation to correct errors; and
Means for providing power to all components of the system.

2. The system of claim 1, where an MCU is located on the sensor node.

3. The system of claim 1, where a sensor node is attached to a moveable segment of a subject and more than one moveable segment has a sensor node attached to it.

4. The system of claim 1, where multiple sensor nodes send raw sensor data to one MCU.

5. The system of claim 1, where the MCU serves, partially or totally, as the means for applying the zero crossing algorithm to the non-corrected orientation data to correct errors, and where the MCU additionally serves as means for storing data.

6. The system of claim 1, where the MCU serves as means for raw sensor data, non-corrected orientation data, and/or error corrected orientation data to pass to the means for storing data.

7. The system of claim 1, where the sensor node additionally comprises more than one of any of: accelerometer, gyroscope, magnetometer, or MCU.

8. The system of claim 1, where the sensor node additionally comprises a GPS device.

9. The system of claim 1, where the MCU serves as the means for applying the zero crossing algorithm to the non-corrected orientation data to correct errors.

10. The system of claim 1, where the means for applying the zero crossing algorithm to the non-corrected orientation data to correct errors is located on the same “unit” as the MCU.

11. The system of claim 1, where the sensor node, MCU and means for applying the zero crossing algorithm to the non-corrected orientation data to correct errors are on the same “unit”.

12. The system of claim 1, which additionally comprises:
Means for storing data; and
Means for data to pass to the means for storing data.

13. The system of claim 1, which additionally comprises:
Means for converting the error corrected orientation data to a graphical representation of the orientation and movement of a subject or segments to which sensor nodes are attached;
Means for display of the graphical representation of the orientation and movement of the subject or segments to which the sensor node or nodes are attached; and
Means for graphical representation data to pass to the means for display.

14. The system of claim 13, where the graphical representation is displayed in real time.

15. The system of claim 13, where the graphical representation is displayed at a later time.

16. The system of claim 1, which additionally comprises a means for analyzing the error corrected orientation data and comparing the error corrected orientation data to other data.

17. The system of claim 1, which additionally comprises a means for the MCU to send control signals to the sensor node.

18. The system of claim 1, which additionally comprises a means for sending control signals to the subject or segment to which the sensor node is attached.

19. The system of claim 1, where a sensor node or nodes are placed on the ground, or on a stationary object in contact with the ground, for the purpose of measuring seismic activity.

20. A method of tracking motion and calculating error corrected orientations, comprising the steps of:
Aligning the axes of an accelerometer, gyroscope, and magnetometer on a sensor node;
Attaching a sensor node to the subject or segment of a subject to be tracked;
Capturing instantaneous data over time from the accelerometer, gyroscope, and magnetometer comprising the sensor node;
Transferring all or a portion of the raw sensor data in sets over time from the sensor node to a processor;
Calculating with a processor the non-corrected orientation of the sensor node using each set of raw sensor data;
Monitoring the accelerometer data with a processor and identifying points in time where the magnitude of the acceleration is below a predefined threshold. These points in time are defined as the zero crossings; and
Applying with a processor the zero crossing error correction algorithm to each calculated orientation.

21. The method of claim 20, where at the beginning, the magnetometer is additionally calibrated to correct for the presence of ferrous or magnetic materials in close proximity to the sensor node which produce a local magnetic field. Calibration steps are comprised of the following:
Measuring the direction of geomagnetic field with a magnetometer on a sensor node, while a sensor node is isolated from any other ferrous magnetic material;
Attaching the sensor node to the ferrous or magnetic material, while keeping track of gyroscope data to ascertain the position of the sensor node;
Using known data of geomagnetic field and orientation of sensor node and data from the magnetometer measuring the total magnetic field to calculate the local magnetic field due to the ferrous or magnetic material; and
Storing local magnetic field data to be subtracted from future magnetometer readings.

22. The method of claim 20, where the output data rate (ODR) of the sensors is a constant fixed rate.

23. The method of claim 20, where a processor additionally transmits instructions in real time to the sensor node to vary the output data rate (ODR) of the sensors, based on the rate of change of the orientations; so that the processor sends instructions to decrease ODR for slower motions, and increase ODR for faster motions. The threshold for ODR rate change may be based on the system power requirements (i.e. data transfer rates require less power) or based on real time display requirements (i.e. smooth graphical display requires faster ODR for fast motions).

24. The method of claim 20, where raw sensor data is stored in memory, and later used to calculate orientations and error corrections.

25. The method of claim 20, additionally comprising the step of transmitting error corrected orientation data to a means for storing the data.

26. The method of claim 20, additionally comprising the step of using the error corrected orientation data to update the graphical representation of the orientation of an onscreen, displayed object.

27. The method of claim 20, additionally comprising the steps of:
Measuring as a function of time the error corrected orientation, acceleration, and velocity data of a subject's body segments, including subjects that are athletes, patients, soldiers, trainees or workers;
Comparing the measured data with expected, ideal, or target orientations, accelerations, and/or velocities;
Calculating the difference between the measured motion data, and the target motion data; and
Using the calculated differences in magnitude, duration, frequency, or change over time as a diagnostic tool to determine health, fitness level, or skill of subject, or as a development tool to increase the performance or skill level of a subject.

28. The method of claim 20, additionally comprising the step of using the error corrected orientations, accelerations, and velocities to determine the most productive, effective, or time efficient means of performing an action or task.

29. The method of claim 20, where a processor monitors the accelerometer raw sensor data for zero crossings; where the processor sends raw sensor data of the gyroscope to a second processor for orientation determination; where the processor only sends raw sensor data from the magnetometer and accelerometer to the other processor when zero crossings are obtained;
where the second processor performs zero crossing error correction when it receives the accelerometer and magnetometer raw sensor data.

30. The method of claim 20, additionally comprising the steps of:
Measuring the error corrected orientation of a subject or segment of a subject;
Comparing the measured orientations to the subject's or segment's desired or anticipated orientation;
Creating an orientation correction feedback loop where orientation correction instructions are calculated, quantifying the difference in measured vs desired orientations. These instructions are fed back to the subject or segment to make actual orientation adjustments.

31. The method of claim 20, additionally comprising the steps of: sending instructions, either through programming or specific requests, to the subject or segment of a subject to perform certain motions or lack of motion, which periodically results in zero crossing accelerations.

32. The method of claim 20, additionally comprising the step of:
Periodically transmitting instructions from the processor to the subject or segment to stop moving, causing periodic zero acceleration.

33. A method of monitoring and correcting the position of solar panels, comprising the steps of claim 30, where the subject is mechanical component attached to a solar panel.

34. A method of adjusting position and orientation of a vehicle, whether it be flying, driving, floating, or submersible, comprising the steps of claim 30, where the subject is a vehicle.

35. A method of recording the position and movement of the endpoint of a segment, comprising the method of claim 20, and additionally comprising the steps of:
Using the error corrected orientation data, calculating with the processor the position of the endpoint of a segment; and
Displaying a graphical representation of the movement of the endpoint of the segment, which may be interpreted as drawing, painting, or writing.

36. A method of deriving suggested modifications or adjustments to future movements of a subject or segment, and of tracking historical variations or anomalies relative to ideal or recommended motion of the subject or segment, comprising the method of claim 20.

37. The method of claim 20, further comprised of using data concerning the speed or quality of completing tasks of biomechanical motion, to determine most time or cost efficient motion to accomplish such task.

38. The method of claim 20, where the subjects to be tracked are elements of a portion or all of a construction project (e.g. individual beams, struts etc.), and additionally comprising the steps of: monitoring the subjects during construction and/or post construction for diagnostic (e.g. post-earthquake damage assessments) or other concerns.

39. A method of calibrating a magnetometer to correct for the presence of ferrous or magnetic materials in close proximity to the sensor node which produce a local magnetic field. Calibration steps are comprised of the following:
Measuring the direction of the geomagnetic field with a magnetometer on a sensor node, while the sensor node is isolated from any other ferrous magnetic material;
Attaching the sensor node to the ferrous or magnetic material, while keeping track of gyroscope data to ascertain the position of the sensor node;
Using the known data of the geomagnetic field and orientation of the sensor node and data from the magnetometer measuring total magnetic field to calculate the local magnetic field due to the ferrous or magnetic material; and
Storing local magnetic field data to be subtracted from future magnetometer readings.
